(19) United States
(12) Patent Application Publication
(10) Pub. No.: US 2016/0310988 A1
(43) Pub. Date: Oct. 27, 2016

(54) MASK ASSEMBLY, A METHOD OF MANUFACTURING A MASK ASSEMBLY, AND A METHOD OF MANUFACTURING DISPLAY DEVICE

(71) Applicant: Samsung Display Co., Ltd., Yongin-si (KR)

(72) Inventors: Sangshin LEE, Yongin-si (KR); Mingoo KANG, Yongin-si (KR)

(21) Appl. No.: 14/954,302

(22) Filed: Nov. 30, 2015

(30) Foreign Application Priority Data
Apr. 27, 2015 (KR) 10-2015-0059102

(51) Int. Cl. B05D 1/32; B05D 1/02

(52) U.S. Cl. CPC B05D 1/32; B05D 1/02

(57) ABSTRACT

This application provides a mask assembly, a method of manufacturing the mask assembly, and a method of manufacturing a display device. The mask assembly includes a mask frame, an auxiliary member installed on the mask frame, and a mask sheet welded to the auxiliary member. A welding recess is formed in the auxiliary member. A first welding point is formed in the welding recess. The first welding point is configured to weld the auxiliary member to the mask frame, and a second welding point is formed at a position of the mask sheet that is different from the welding recess formed in the auxiliary member.

### CROSS-REFERENCE TO RELATED APPLICATION

This application claims priority from and the benefit of Korean Patent Application No. 10-2015-0059102, filed on Apr. 27, 2015, which is hereby incorporated by reference for all purposes as if fully set forth herein.

### BACKGROUND

1. Field

Exemplary embodiments relate to a mask assembly, a method of manufacturing a mask assembly, and a method of manufacturing a display device using the mask assembly.

2. Discussion of the Background

Mobile electronic devices are widely used. Mobile phones, tablets, smart is watches, and laptops are some examples of these mobile electronic devices. Mobile electronic devices typically include a display device to provide visual information to a user. Because consumers demand thin and light mobile electronic devices, sizes of display devices have been correspondingly minimized. However, the importance of the display device has increased because the display now plays a central role in mobile electronic devices as a touch capable display. Mobile electronic devices with a bendable display have recently been developed, further complicating the devices.

The display device may include multiple layers using multiple methods for various layers. For example, various layers of the display device may be formed by using a chemical vapor deposition (CVD) method, an evaporation method, etc. Masks may be incorporated into these methods.

The above information disclosed in this Background section is only for enhancement of understanding of the background of the inventive concept, and, therefore, it may contain information that does not form the prior art that is already known in this country to a person of ordinary skill in the art.

### SUMMARY

Exemplary embodiments include a mask assembly, a method of manufacturing the mask assembly, and a method of manufacturing a display device with a mask assembly.

General and specific aspects may be embodied by using a system, a method, a computer program, or combination of any system, method, computer program. Additional aspects will be set forth in part in the description which follows, and, in part, will be apparent from the disclosure, or may be learned by practice of the inventive concept.

An exemplary embodiment discloses a mask assembly that includes a mask frame, an auxiliary member installed on the mask frame, and a mask sheet welded to the auxiliary member. A welding recess is formed in the auxiliary member. A first welding point is formed in the welding recess. The first welding point is configured to weld the auxiliary member to the mask frame, and a second welding point is formed at a position of the mask sheet that is different from the welding recess formed in the auxiliary member.

An exemplary embodiment also discloses a method of manufacturing a mask assembly. The method includes setting an auxiliary member on a mask frame, welding the auxiliary member to the mask frame by forming a first welding point in a welding recess of the auxiliary member, disposing a mask sheet on the auxiliary member, and welding the mask sheet to the auxiliary member by forming a second welding point in a different position than the first welding point.

An exemplary embodiment also discloses a method of manufacturing a display device. The method includes introducing a mask assembly into a chamber, aligning the mask assembly with a first substrate, and spraying a deposition material from a deposition source to the mask assembly to deposit the deposition material on the first substrate. The mask assembly includes a mask frame, an auxiliary member installed on the mask frame, and a mask sheet welded to the auxiliary member. A welding recess is formed in the auxiliary member. A first welding point is formed in the welding recess and is configured to weld the auxiliary member to the mask frame. A second welding point is formed on the mask sheet at a different position than the welding recess.

The foregoing general description and the following detailed description are exemplary and explanatory and are intended to provide further explanation of the claimed subject matter.

### BRIEF DESCRIPTION OF THE DRAWINGS

The accompanying drawings, which are included to provide a further understanding of the inventive concept, and are incorporated in and constitute a part of this specification, illustrate exemplary embodiments of the inventive concept, and, together with the description, serve to explain principles of the inventive concept.

FIG. 1 is a conceptual view illustrating a display device manufacturing apparatus including a mask assembly according to an exemplary embodiment.

FIG. 2 is a perspective view illustrating an exemplary embodiment of the mask assembly illustrated in FIG. 1.

FIG. 3 is a cross-sectional view taken along sectional line II-II′ of FIG. 2.

FIG. 4A, FIG. 4B, and FIG. 4C are plan views illustrating the positions of a first welding point and a second welding point illustrated in FIG. 2.

FIG. 5 is a perspective view illustrating an exemplary embodiment of the mask assembly illustrated in FIG. 1.

FIG. 6 is a cross-sectional view taken along sectional line V-V′ of FIG. 5.

FIG. 7 is a cross-sectional view illustrating a portion of a display device manufactured via the display device manufacturing apparatus illustrated in FIG. 1.

### DETAILED DESCRIPTION OF THE ILLUSTRATED EMBODIMENTS

In the following description, for the purposes of explanation, numerous specific details are set forth in order to provide a thorough understanding of various exemplary embodiments. It is apparent, however, that various exemplary embodiments may be practiced without these specific details or with one or more equivalent arrangements. In other instances, well-known structures and devices are shown in block diagram form in order to avoid unnecessarily obscuring various exemplary embodiments.

In the accompanying figures, the size and relative sizes of layers, films, panels, regions, etc., may be exaggerated for clarity and descriptive purposes. Also, like reference numerals denote like elements.

When an element or layer is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. Like numbers refer to like elements throughout. As used herein, the term “and/or” includes any and all combinations of one or more of the associated listed items.

Although the terms “first,” “second,” etc. may be used herein to describe various elements, components, regions, layers, and/or sections, these elements, components, regions, layers, and/or sections should not be limited by these terms. These terms are used to distinguish one element, component, region, layer, and/or section from another element, component, region, layer, and/or section. Thus, a first element, component, region, layer, and/or section discussed below could be termed a second element, component, region, layer, and/or section without departing from the teachings of the present disclosure.

Spatially relative terms, such as “beneath,” “below,” “lower,” “above,” “upper,” and the like, may be used herein for descriptive purposes, and, thereby, to describe one element or feature's relationship to another element(s) or feature(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof.

Various exemplary embodiments are described herein with reference to sectional illustrations that are schematic illustrations of idealized exemplary embodiments and/or intermediate structures. As such, variations from the shapes of the illustrations as a result, for example, of manufacturing techniques and/or tolerances, are to be expected. Thus, exemplary embodiments disclosed herein should not be construed as limited to the particular illustrated shapes of regions, but are to include deviations in shapes that result from, for instance, manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the drawings are schematic in nature and their shapes are not intended to illustrate the actual shape of a region of a device and are not intended to be limiting.

Unless otherwise defined, all terms (including technical and scientific terms) used herein have the same meaning as commonly understood by one of ordinary skill in the art to which this disclosure is a part. Terms, such as those defined in commonly used dictionaries, should be interpreted as having a meaning that is consistent with their meaning in the context of the relevant art and will not be interpreted in an idealized or overly formal sense, unless expressly so defined herein.

In the following examples, the x-axis, the y-axis and the z-axis are not limited to three axes of the rectangular coordinate system, and may be interpreted in a broader sense. For example, the x-axis, the y-axis, and the z-axis may be perpendicular to one another, or may represent different directions that are not perpendicular to one another.

When a particular exemplary embodiment is implemented differently, a specific process order may be performed differently from the described order. For example, two consecutively described processes may be performed substantially at the same time or performed in an order opposite to the described order.

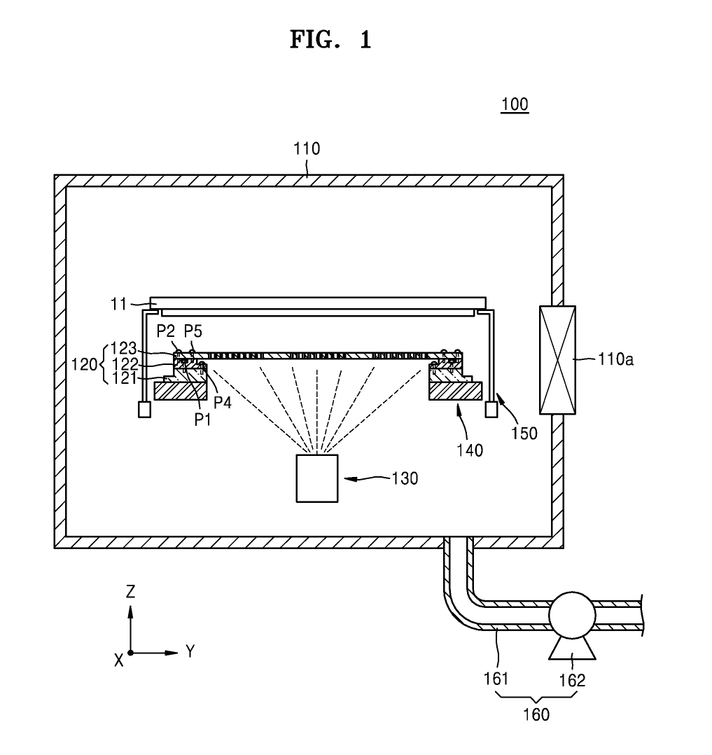

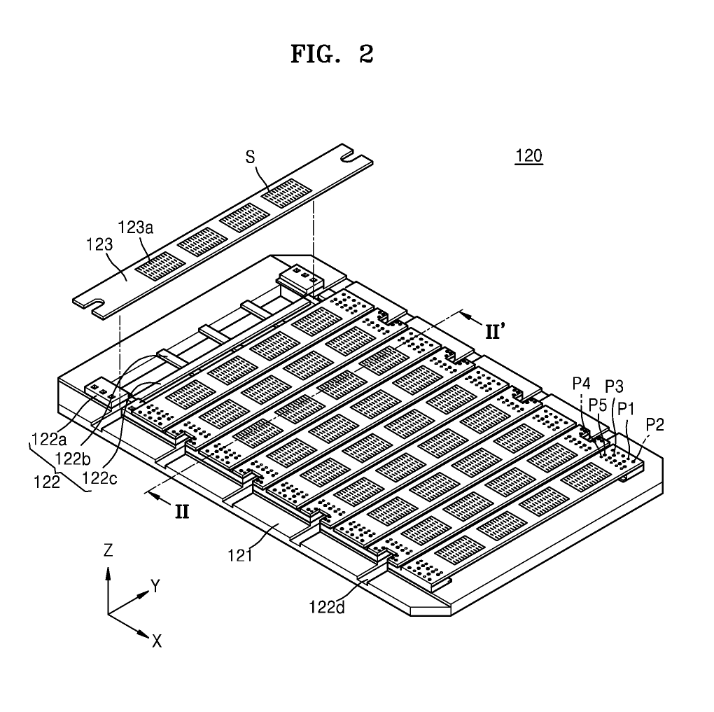

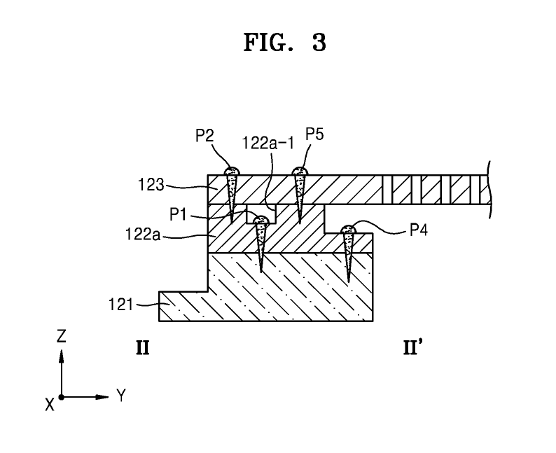

FIG. 1 is a conceptual view illustrating a display device manufacturing apparatus including a mask assembly according to an exemplary embodiment. FIG. 2 is a perspective view illustrating an exemplary embodiment of the mask assembly illustrated in FIG. 1. FIG. 3 is a cross-sectional view taken along sectional line II-II′ of FIG. 2.

Referring to FIGS. 1, 2, and 3, a display device manufacturing apparatus 100 may include a chamber 110, a mask assembly 120, a deposition source 130, a support portion 140, a holder 150, and a pressure adjuster 160.

The chamber 110 may have a space formed in its inside, and may be formed such that a portion of the chamber 110 is open. At this location, a gate valve 110a may be installed on the open portion of the chamber 110 to open and close the open portion of the chamber 110.

The mask assembly 120 may include a mask frame 121, an auxiliary member 122, and a mask sheet 123. The mask frame 121 may be formed in a quadrangular shape. For example, the mask frame 121 may be formed such that a central portion thereof is open.

The auxiliary member 122 may be formed in various shapes. For example, the auxiliary member 122 may have a plate shape installed on the mask frame 121. Also, the auxiliary member 122 may be installed on the mask frame 121 and may include a blocking mask (not shown) formed in a grating shape. Hereinafter, for ease of reference, the auxiliary member is described as having a plate shape.

Referring to FIGS. 2 and 3, the auxiliary member 122 may include a first auxiliary member 122a installed at a portion on which the mask sheet 123 is seated, a second auxiliary member 122b installed on the central portion of the mask frame 121 and disposed in a long side direction of the mask frame 121 (e.g., along the X-axis), and a third auxiliary member 122c disposed between mask sheets 123 and disposed in a substantially perpendicular direction (e.g., along the Y-axis) compared to the second auxiliary member 122b.

Referring to FIG. 3, the first auxiliary member 122a may be welded to the mask frame 121. For example, a portion of the first auxiliary member 122a may be in a half-etched state, and a fourth welding point P4 may be formed at the half-etched portion. Also, a welding recess 122a-1 may be formed in the first auxiliary member 122a. In particular, the welding recess 122a-1 may be formed such that the welding recess 122a-1 is concave from one side of the first auxiliary member 122a. The welding recess 122a-1 may be formed in an area corresponding to where the first welding point P1 is formed.

In an exemplary embodiment, a mask assembly 120 includes multiple welding recess 122a-1. For example, the multiple welding recesses 122a-1 may be formed in a straight line, and may be formed such that they alternate in zigzag pattern.

Referring to FIG. 2, the mask sheet 123 may be formed in a plate shape, and may include at least two second openings 123a. A deposition material may pass through the at least two second openings 123a. The second openings 123a may be formed in the mask sheet 123 to be separated from each other with a predetermined interval.

A mask assembly 120 may include multiple mask sheets 123. In this case, the multiple mask sheets 123 may be disposed such that they are separated from each other in the long side direction (e.g., X-axis direction) of the mask frame 121.

A second welding point P2 may be formed on the mask sheet 123. Multiple second welding points P2 may be formed on the mask sheet 123 and may form a straight line. In another exemplary embodiment, the second welding points P2 may be disposed in a zigzag pattern.

The welding recess 122a-1 and the second welding point P2 may be arranged by various methods. For example, the welding recess 122a-1 and the second welding point P2 may be alternately arranged such that the welding recess 122a-1 and the second welding point P2 may be arranged in a zigzag pattern. As an alternate example, the welding recess 122a-1 and the second welding point P2 may be alternately arranged to by forming one straight line.

As another exemplary embodiment, the welding recess 122a-1 may be arranged to form a first straight line, and the second welding point P2 may be arranged to form a second straight line that is different from the first straight line. The first straight line and the second straight line may be disposed such that they are parallel or substantially parallel to each other.

As shown in FIG. 3, the welding recess 122a-1 may be formed inside the first auxiliary member 122a rather than the outermost side of the first auxiliary member 122a. Although not illustrated in FIG. 2, FIG. 3 illustrates that the second welding point P2 may be disposed closer to the edge of the first auxiliary member 122a than the welding recess 122a-1. Specifically, the second welding point P2 may be formed at the edge of the first auxiliary member 122a which is the outermost side of the mask frame 121. The welding recess 122a-1 may be formed in the first auxiliary member 122a such that the welding recess 122a-1 is closer to the inside of the mask frame 121 than the second welding point P2. Therefore, the second welding point P2 may prevent the mask sheet 123 from floating at the edge of the first auxiliary member 122a.

Referring to FIG. 2, third welding point P3 may be formed in the lengthwise direction of the mask sheet 123 may be formed on the mask sheet 123. The third welding point P3 may solidly fix the mask sheet 123 to the first auxiliary member 122a.

Referring to FIGS. 2 and 3, a fifth welding point P5 may be formed on the mask sheet 123 such that the fifth welding point P5 is disposed between the fourth welding point P4 and the first welding point Pl. The fifth welding point P5 may be disposed further from the mask frame 121 (e.g., on the outer side) than the fourth welding point P4.

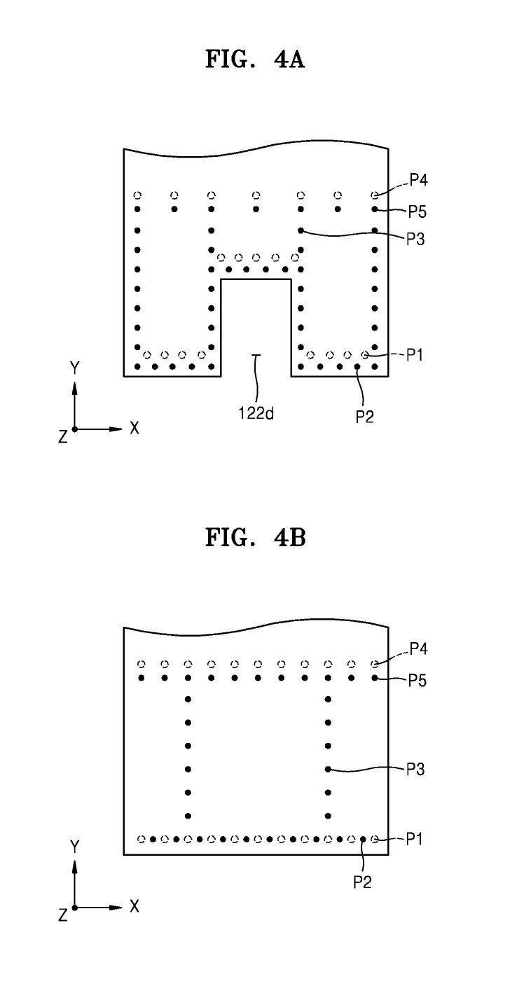

FIGS. 4A, 4B, and 4C are plan views illustrating the positions of a first welding point and a second welding point illustrated in FIG. 2.

Referring to FIG. 4A, a second welding point P2 may be formed on the outermost portion of the mask sheet 123 in the long side (e.g., along the Y-direction). For example, the second welding point may be closest to the short side edge of the mask sheet 123 in the long side direction (e.g., along the Y-direction) than any other welding point. A first welding point P1 may be formed on an outer portion of the first auxiliary member 122a such that the first welding point P1 corresponds to second closest welding point to the short side edge of the mask sheet 123. Two second welding points P2 may be formed such that the first welding point P1 is disposed between two second welding points P2 in the X-direction but the first welding point P1 is further from the short side edge of the mask sheet 123 (e.g., in the Y-direction). The first welding point P1 and the second welding point P2 may be arranged around an insert recess 122d.

A fourth welding point P4 may be formed on the first auxiliary member 122a such that the fourth welding point P4 corresponds to furthest welding point from the short side edge of the mask sheet 123. A fifth welding point P5 may be formed on the mask sheet 123 such that the fifth welding point P5 is the second furthest welding point from the short side edge of the mask sheet 123. The fifth welding point P5 may be disposed between the first welding point P1 and the fourth welding point P4 in the Y-direction. A third welding point P3 may be formed on the mask sheet 123 such that the third welding point P3 is disposed between fifth welding point P5 and the first welding point P1 in the Y-direction. The third welding point may be aligned with the first welding point in the X-direction.

FIG. 4B is similar to FIG. 4A, except that FIG. 4B does not have an insert recess 122d and that first welding point P1 and the second welding point P2 are equidistant from the short side edge of the mask sheet 123. Thus, the welding point P1 and welding point P2 may be aligned in the Y-direction. The second welding point P2 is also formed between the first welding point P1 in the X-direction.

FIG. 4C is similar to FIG. 4A, except FIG. 4C does not include a third welding point P3 and that welding point P1 and welding point P2 may be alternately formed in two rows. The first welding point P1 and the second welding point P2 may equidistant (e.g., aligned in the Y-direction) from the short side edge of the mask sheet 123 in the first row. The first welding point P1 and the second welding point P2 may equidistant from the short side edge of the mask sheet 123 in the second row. The first row may be closer to the short side edge of the mask sheet 123 than the second row. The first welding point P1 of the second row may be disposed between the first and second welding point P1, P2 of the first row.

Hereafter, a method of manufacturing the mask assembly 120 will be described. First, the first auxiliary member 122a, the second auxiliary member 122b, and the third auxiliary member 122c may be installed on the mask frame 121. During installation, the first auxiliary member 122a, the second auxiliary member 122b, and the third auxiliary member 122c may be fixed to the mask frame 121 by laser welding or any other suitable process. In particular, the first auxiliary member 122a and the mask frame 121 may be coupled to each other by performing welding on the half-etched portion of the first auxiliary member 122a. Also, the first auxiliary member 122a and the mask frame 121 may be fixed to each other by forming the first welding point P1 on the welding recess 122a-1 by laser welding or any other suitable process. The first auxiliary member 122a and the mask frame 121 may be fixed to each other by forming a fourth welding point P4. The first welding point P1 and the fourth welding point P4 may be formed at the same time or at different times.

When the above process is completed, the mask sheet 123 may be arranged on the first auxiliary member 122a and the mask sheet 123 may be installed on the first auxiliary member 122a by laser welding or any other suitable process with the mask sheet 123 extended. As described above, the second welding point P2 is not formed on the upper surface of the first welding point P1 but may be formed on the outer portion compared to the first welding point P1. In particular, the second welding point P2 may be formed on a portion of the mask sheet 123 that is further from the center of the mask frame 121 than the first welding point P1.

As described above, the third welding point P3 may be formed while the second welding point P2 is formed. Third welding point P3 may be formed in the same way as or similarly as the second welding point P2.

When the installation of the mask sheet 123 is completed, the end of the mask sheet 123 may be cut and removed. The mask sheet 123 may be cut to correspond to the shape of the mask frame 121 and the first auxiliary member 122a.

Specifically, an insert recess 122d (shown in FIG. 2) may be formed in at least one of the mask frame 121 and the first auxiliary member 122a so that a tool, such as a lifter (or any other suitable tool) used by the display device manufacturing apparatus 100, may be inserted in the insert recess 122d. The insert recess 122d may be formed in at least one of the long side (e.g., along the X-axis) and the short side (e.g., along the Y-axis) of the mask frame 121.

The mask sheet 123 may be cut such that the insert recess 122d is exposed. Therefore, the end of the mask sheet 123 may be different depending on the shape of the insert recess 122d. In this case, the welding recess 122a-1 may be configured such that the welding recess 122a-1 is separated further from the insert recess 122d than the second welding point P2. Thus, the second welding point P2 may be formed on the outermost side of a cut portion of the mask sheet 123.

Since the outermost side of the first auxiliary member 122a may be half-etched, the end of a mask sheet 123 may be separated from the first auxiliary member 122a during installation. To prevent the separation, the mask sheet 123 may be welded with the outermost side of the first auxiliary member 122a that is not half-etched, the first welding point P1 may overlap the second welding point P2 or a gap between the mask sheet 123 and the first auxiliary member 122a may be generated by the first welding point P1 so that the mask sheet 123 and the first auxiliary member 122a may not be solidly welded to each other. However, the mask assembly 120 according to an exemplary embodiment may prevent floating of the mask sheet 123 by forming the second welding point P2 on the outermost portion of the mask sheet 123. Also, the mask assembly 120 may prevent generation of a gap between the mask sheet 123 and the first auxiliary member 122a due to forming the welding recess 122a-1 and forming the first welding point P1 inside the welding recess 122a-1.

Referring to FIG. 1, after a deposition material is inserted inside the deposition source 130, the deposition source 130 may spray the deposition material to the mask assembly 120 by applying heat to the deposition material. Also, the support portion 140 may support the mask assembly 120. The support portion 140 may align the position of the mask assembly 120 by moving the mask assembly 120 in at least one direction (e.g., the X-direction, the Y-direction, the Z-direction, or some combination of these directions).

The holder 150 may support a first substrate 11. The holder 150 may be formed in various shapes. For example, the holder 150 may be formed in a shape of a lift that may ascend/descend. The first substrate 11 may be supplied from the outside of the chamber 110, disposed on the mask assembly 120, and supported by the ascending/descending holder 150. Specifically, the holder 150 may be disposed on at least one of the long side and the short side of the mask assembly 120. Also, a portion of the holder 150 may ascend/descend while it is inserted into the insert recess 122d.

In an exemplary embodiment, the holder 150 may be formed in a shuttle shape and at least one of the first substrate 11 and the deposition source 130 deposits a deposition material on the first substrate 11 while the first substrate 11 is moved linearly. For example, the holder 150 may allow the first substrate 11 to move linearly by holding the edge portion of the first substrate 11 and then moving the first substrate linearly. The holder 150 may not be inserted to the insert recess 122d, and the insert recess 122d may not exist. However, for ease of reference, the holder 150 is described as being formed in a lift shape.

The pressure adjuster 160 may include a connection pipe 161 connected to the chamber 110. The pressure adjuster 160 may also include a pump 162 installed on the connection pipe 161. The inner pressure of the chamber 110 may be adjusted to vacuum, atmospheric pressure, or some pressure between atmospheric and vacuum depending on the particular operation of the pump 162.

After the pressure adjuster 160 sets the inner pressure of the chamber 110 to atmospheric pressure, the gate valve 110a may operate to open the open portion of the chamber 110.

After the mask assembly 120 and the first substrate 11 are inserted into the chamber 110 by a robot arm, a shuttle, or some other suitable means, the mask assembly 120 and the first substrate 11 may be disposed on the support portion 140 and the holder 150, respectively. Movements of the mask assembly 120 and the first substrate 11 may be performed sequentially or simultaneously.

When the mask assembly 120 and the first substrate 11 are disposed, the mask assembly 120 may be aligned with the first substrate 11 by comparing the positions of the mask assembly 120 and the first substrate 11 with each other. The support portion 140 may align the mask assembly 120 with the first substrate 11 by accurately moving the mask assembly 120.

When the deposition source 130 sprays the deposition material, the deposition material may pass through the mask assembly 120 and may be deposited on the first substrate 11. The deposition material may form a predetermined pattern while passing through a second opening 123a as shown in FIG. 3. The third auxiliary member 122c may prevent the deposition material from passing between adjacent mask sheets 123.

Therefore, the display device manufacturing apparatus 100 and the display device manufacturing method may coat the deposition material in a fine pattern on the first substrate 11 by using an accurately manufactured mask assembly 120. Also, the display device manufacturing apparatus 100 and the display device manufacturing method may prevent destruction and interference, etc. of other elements due to a floating portion of the mask sheet 123 by using the mask assembly 120 with a non-floating mask sheet 123 according to an exemplary embodiment.

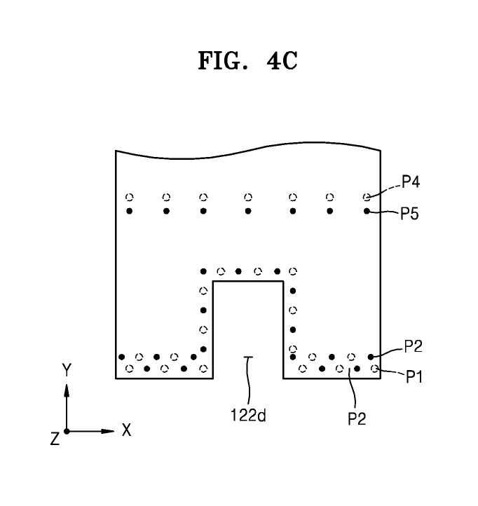

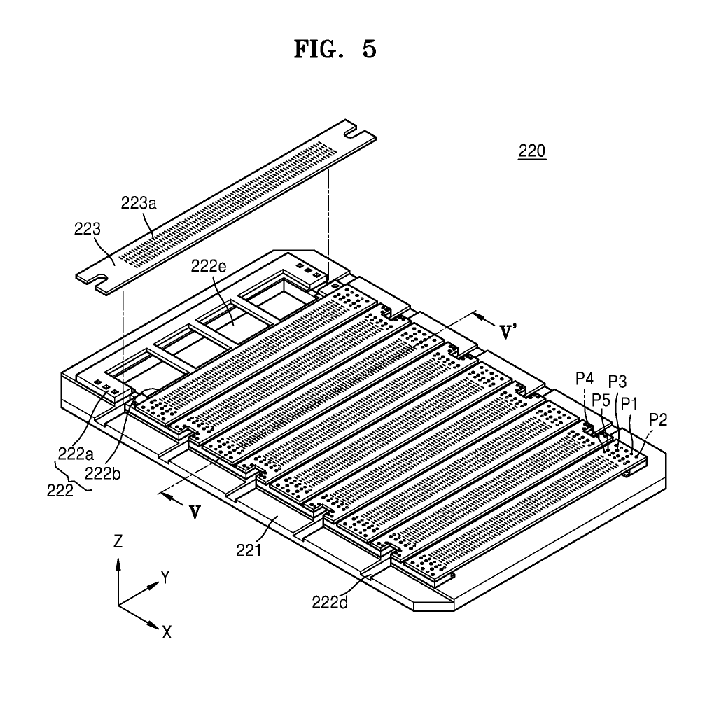

FIG. 5 is a perspective view illustrating an exemplary embodiment of the mask assembly illustrated in FIG. 1. FIG. 6 is a cross-sectional view taken along sectional line V-V′ of FIG. 5.

Referring to FIGS. 5 and 6, a mask assembly 220 may include a mask frame 221, an auxiliary member (not shown), and a mask sheet 223. Because the mask frame 221 and the mask sheet 223 are the same as or similar to those described with reference to FIGS. 1 to 3, their detailed descriptions thereof are omitted for brevity.

The auxiliary member may include a blocking mask 222 in which a first opening 222e is formed. The blocking mask 222 may include multiple first openings 222e. The blocking mask 222 may be formed in a grate shape.

The blocking mask 222 may be installed on the mask frame 221. The blocking mask 222 may include a body portion 222a forming an edge and a grating member 222b forming the grate-shaped first opening 222e inside the body portion 222a. The first opening 222e may have a size similar to a size for manufacturing one display device. Thus, each blocking mask 222 may form more than one display device.

The body portion 222a may be formed similarly to the above-described first auxiliary member 122a. The inner side of the body portion 222a may be half-etched. Also, a welding recess 222a-1 may be formed in the body portion 222a, and a first welding point P1 may be formed inside the welding recess 222a-1 to weld the body portion 222a to the mask frame 221. The mask sheet may be disposed on the body portion 222a.

As described above, a second welding point P2 may be formed on the outermost side of the body portion 222a. Also, a third welding point P3 may be arranged to form a predetermined angle with respect to a line formed by the second welding point P2.

The welding recess 222a-1 and the second welding point P2 may be arranged in various methods as described above. For example, the welding recess 222a-1 and the second welding point P2 may form straight lines, respectively, and the respective straight lines may be formed at different positions. In another exemplary embodiment, the welding recess 222a-1 and the second welding point P2 may be formed alternately, and the welding recess 222a-1 and the second welding point P2 may form one straight line or may be formed in zigzag pattern.

An insert recess 222d may be formed in at least one of the mask frame 221 and the blocking mask 222. The insert recess 222d may be formed in a portion where the mask frame 221 and the blocking mask 222 overlap each other. Also, the insert recess 222d may be already formed in the mask frame 221 and the blocking mask 222 or the insert recess 222d may be formed later.

A manufacturing sequence of the mask assembly 220 is described. After the blocking mask 222 is seated on the mask frame 221, welding may be performed. Welding may be performed on a half-etched portion of the blocking mask 222 to form a fourth welding point P4. Also, the first welding point P1 may be formed on the welding recess 222a-1 to fix the mask frame 221 and the blocking mask 222 together.

The mask sheet 223 may then be fixed to the blocking mask 222 by welding. The blocking mask 222 and the mask sheet 223 may be coupled together by forming the second welding point P2, a third welding point P3, and a fifth welding point P5 on the mask sheet 223. Also, both ends of the mask sheet 223 may be cut with reference to the second welding point P2 formed on the outermost portion.

The above-manufactured mask assembly 220 may prevent the end of the mask sheet 223 from floating. In particular, after the mask sheet 223 is extended, the mask sheet 223 may be installed at an accurate position, so that accurate manufacturing is possible according to the mask assembly 220.

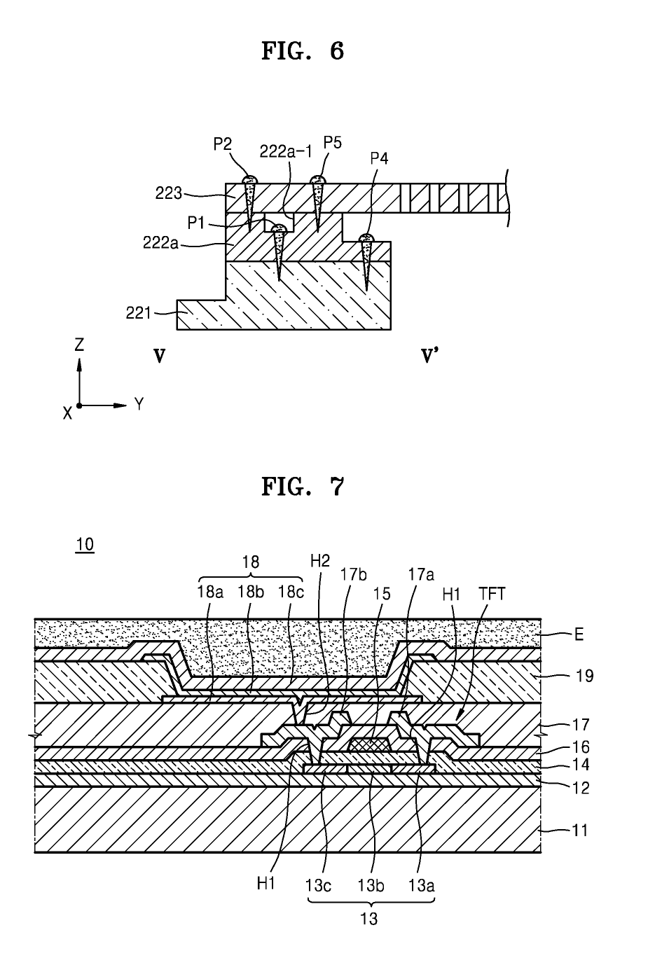

FIG. 7 is a cross-sectional view illustrating a portion of a display device manufactured via the display device manufacturing apparatus illustrated in FIG. 1.

Referring to FIG. 7, the display device manufacturing apparatus 100 of FIG. 1 may form various layers of the display device 10. A deposition material may include an organic material, metal, an inorganic material, etc. However, hereinafter, ease of reference, a deposition material is described as an organic material, and an interlayer is formed by depositing the organic deposition material.

The display device 10 may include the first substrate 11 and an emission portion (not shown). The display device 10 may also include a thin film encapsulating layer E formed on the upper portion of the emission portion, or a second substrate (not shown). Because the second substrate is the same as or similar to a substrate used for a general display device, its detailed description is omitted for brevity. Also, hereinafter, for ease of reference, the display device 10 is described as including the thin film encapsulation layer E. However, it should be noted that the device may had a different encapsulation layer or this layer may be omitted from the display device 10.

The emission portion of the display device 10 may include a thin film transistor (TFT) and a passivation layer 17 may be formed to cover the TFT. The emission portion may also an organic light-emitting device (OLED) 18 formed on the passivation layer 17.

The first substrate 11 may include a glass material or any other suitable material. The first substrate 11 may include a plastic material, such as polyimide (PI). The first substrate may include a metal material, such as stainless steel, titanium, or an alloy of stainless steel or titanium. Hereinafter, for ease of reference, the first substrate 11 is described as including a glass material.

A buffer layer 12 may include an organic compound and/or an inorganic compound may be further formed on the upper surface of the first substrate 11. The buffer layer may include at least one of SiOₓ (x≧1) and SiNₓ (x≧1).

An active layer 13 may be arranged in a predetermined pattern and formed on the buffer layer 12. The active layer 13 may be covered (buried) by a gate insulating layer 14. The active layer 13 may include a source region 13a, a drain region 13c, and a channel region 13b disposed between the source region 13a and the drain region 13c.

This active layer 13 may include various materials. For example, the active layer 13 may include inorganic semiconductor material such as amorphous silicon or crystalline silicon. In another example, the active layer 13 may include an oxide semiconductor. In another example, the active layer 13 may include an organic semiconductor material. However, hereinafter, for ease of reference, the active layer 13 is described as including amorphous silicon.

This active layer 13 may be formed by forming an amorphous silicon layer on the buffer layer 12, and then crystallizing the amorphous silicon layer to form a polycrystalline silicon layer. Forming the active layer 13 may include patterning the polycrystalline silicon layer. The source region 13a and the drain region 13c of the active layer 13 may be doped with impurities depending on the kind of a TFT such as a driving TFT (not shown), a switching TFT (not shown), etc.

A gate electrode 15 corresponding to the active layer 13, and an inter-layer insulating layer 16 covering the gate electrode 15 may be formed on the upper surface of the gate insulating layer 14.

A contact hole H1 may be formed in the inter-layer insulating layer 16. At the same time or at a later time, another contact hole H1 may be formed in the inter-layer insulating layer 16. The gate insulating layer 14, a source electrode 17a, and a drain electrode 17b may be formed on the inter-layer insulating layer 16 to contact the source region 13a and the drain region 13c, respectively, through respective contract holes H1.

The passivation layer 17 may be formed on the upper portion of the above-formed TFT, and a pixel electrode 18a of the OLED 18 may be formed on the passivation layer 17. The pixel electrode 18a may contact the drain electrode 17b of the TFT through a via hole H2 formed in the passivation layer 17. The passivation layer 17 may include an inorganic material and/or an organic material. The passivation layer 17 may be a single layer or two or more layers. The passivation layer 17 may be formed as a planarization layer (i.e., an upper surface is flat regardless of bending of the lower layer) or formed to have bending depending on bending of a layer disposed in the lower portion of the display device. Also, this passivation layer 17 may include a transparent insulator to accomplish a resonance effect.

After the pixel electrode 18a is formed on the passivation layer 17, a pixel defining layer 19 may formed to cover the pixel electrode 18a and the passivation layer 17. The pixel defining layer 19 may be open to expose the pixel electrode 18a. The pixel defining layer 19 may include an organic material and/or an inorganic material.

An interlayer 18b and an opposite electrode 18c may be formed on the pixel electrode 18a. The interlayer 18b and an opposite electrode 18c may also be formed on at least a portion of the pixel defining layer 19.

The pixel electrode 18a may serves as an anode electrode and the opposite electrode 18c may serve as a cathode electrode. The polarities of pixel electrode 18a and opposite electrode 18c may be reversed.

The pixel electrode 18a and the opposite electrode 18c may be insulated from each other by the interlayer 18b. Voltages of different polarities are applied to the interlayer 18b to allow an organic emission layer to emit light.

The interlayer 18b may have an organic emission layer. For example, the interlayer 18b may have an organic emission layer and may further have at least one of a hole injection layer (HIL), a hole transport layer (HTL), an electron transport layer (ETL), and an electron injection layer (EIL) as a common layer (not shown).

One unit pixel may be formed from multiple sub-pixels, and the sub-pixels may emit light of various colors. For example, the sub-pixels may emit light of red, green, and blue. In another example, the sub-pixels may emit light of red, green, blue, and white.

The above-described thin film encapsulation layer E may include multiple inorganic layers or include an inorganic layer and an organic layer.

The organic layer of the thin film encapsulation layer E may include a polymer. The organic layer of the thin film encapsulation layer E may be a single layer or a stacked layer formed of one of polyethylene terephtalate (PET), polyimide (PI), polycarbonate, epoxy, polyethylene (PE), and polyacrylate. The organic layer of the thin film encapsulation layer E a polyacrylates such as a polymerized monomer composition including a diacrylate-based monomer and a triacrylate-based monomer. The monomer composition may further include a monoacrylate-based monomer. Also, the monomer composition may further include a photoinitiator such as trimethyl benzoyl diphenyl phosphine oxide (TPO) or any other suitable material

The inorganic layer of the thin film encapsulation layer E may be a single layer or a stacked layer including a metallic oxide and/or a metallic nitride. Specifically, the inorganic layer may include one of SiNₓ, Al₂O₃, SiO₂, and TiO₂.

An uppermost layer of the thin film encapsulation layer E that is exposed to the outside may include an inorganic layer in order to prevent moisture from contacting the OLED.

In an exemplary embodiment, the thin film encapsulation layer E may include at least one sandwich structure where at least one organic layer is inserted between at least two inorganic layers. For example, the thin film encapsulation layer E may include a first inorganic layer, a first organic layer, and a second inorganic layer sequentially from the upper portion of the OLED 18.

In an exemplary embodiment, the thin film encapsulation layer E may include a sandwich structure where at least one inorganic layer is inserted between at least two organic layers. For example, the thin film encapsulation layer E may include the first organic layer, the first inorganic layer, and a second organic layer sequentially from the upper portion of the OLED 18.

In an exemplary embodiment, the thin film encapsulation layer E may include a sandwich structure where at least one organic layer is inserted between at least two inorganic layers and a sandwich structure where at least one inorganic layer is inserted between at least two organic layers. For example, the thin film encapsulation layer E may include the first inorganic layer, the first organic layer, the second inorganic layer, a second organic layer, and a third inorganic layer sequentially from the upper portion of the OLED 18. In another example, the thin film encapsulation layer E may include the first inorganic layer, the first organic layer, the second inorganic layer, the second organic layer, the third inorganic layer, a third organic layer, and a fourth inorganic layer sequentially from the upper portion of the OLED 18.

A halogenated metal layer including lithium fluoride (LiF) may be additionally included between the OLED 18 and the first inorganic layer. The halogenated metal layer may prevent the OLED 18 from being damaged when the first inorganic layer is formed by using a sputtering method.

The first organic layer may have a narrower area than the second inorganic layer, and the second organic layer may have a narrower area than the third inorganic layer.

The mask assemblies 120, 220 are accurately manufactured, so that the position of the interlayer may be the same as or similar to a designed position.

Therefore, using the accurately manufactured mask assemblies 120, 220 the display device may prevent a defective product or a malfunction by depositing a deposition material. A display device according to an exemplary embodiment also improves an electric characteristic because the display device is accurately manufactured with aligned layers.

Although certain exemplary embodiments and implementations have been described herein, other embodiments and modifications will be apparent from this description. Accordingly, the inventive concept is not limited to such embodiments, but rather to the broader scope of the presented claims and various obvious modifications and equivalent arrangements.

What is claimed is:

1. A mask assembly, comprising:
a mask frame;
an auxiliary member installed on the mask frame; and
a mask sheet welded to the auxiliary member,
wherein:
a welding recess is formed in the auxiliary member;
a first welding point is formed in the welding recess and configured to weld the auxiliary member to the mask frame; and
a second welding point is formed at a position of the mask sheet that is different from the welding recess formed in the auxiliary member.

2. The mask assembly of claim 1, wherein the auxiliary member comprises a blocking mask installed on the mask frame and comprising a first grate-shaped opening.

3. The mask assembly of claim 1, wherein the welding recess and the second welding point are formed to alternate with each other.

4. The mask assembly of claim 1, wherein at least one of the welding recess and the second welding point is disposed in a zigzag pattern.

5. The mask assembly of claim 1, wherein the second welding point is formed closer to a short side edge of the mask sheet than the welding recess.

6. The mask assembly of claim 1, wherein the welding recess is disposed in a first straight line and the second welding point is disposed in a second straight line, and the first straight line and the second straight line are substantially parallel.

7. The mask assembly of claim 1, wherein the second welding point is formed on an outer portion of the mask sheet.

8. A method of manufacturing a mask assembly, the method comprising:
setting an auxiliary member on a mask frame;
welding the auxiliary member to the mask frame by forming a first welding point in a welding recess of the auxiliary member;
disposing a mask sheet on the auxiliary member; and
welding the mask sheet to the auxiliary member by forming a second welding point in a different position than the first welding point.

9. The method of claim 8, wherein the welding recess and the second welding point are formed to alternate with each other.

10. The method of claim 8, wherein at least one of the welding recess and the second welding point is disposed in a zigzag pattern.

11. The method of claim 8, wherein the second welding point is formed closer to a short side edge of the mask sheet than the welding recess.

12. The method of claim 8, wherein the welding recess is disposed in a first straight line and the second welding point is disposed in a second straight line, and the first straight line and the second straight line are substantially parallel.

13. The method of claim 8, wherein the second welding point is formed on an outer portion of the mask sheet.

14. The method of claim 8, further comprising removing a portion of the mask sheet that corresponds to an outermost portion of the second welding point.

15. A method of manufacturing a display device, the method comprising:
introducing a mask assembly into a chamber;
aligning the mask assembly with a first substrate; and
spraying a deposition material from a deposition source to the mask assembly to deposit the deposition material on the first substrate,
wherein the mask assembly comprises:
a mask frame;
an auxiliary member installed on the mask frame; and
a mask sheet welded to the auxiliary member,
wherein:
a welding recess is formed in the auxiliary member and a first welding point is formed in the welding recess and is configured to weld the auxiliary member to the mask frame; and
a second welding point is formed on the mask sheet at a different position than the welding recess.

16. The method of claim 15, wherein the welding recess and the second welding point are formed to alternate with each other.

17. The method of claim 15, wherein at least one of the welding recess and the second welding point is disposed in a zigzag pattern.

18. The method of claim 15, wherein the second welding point is formed outside the welding recess.

19. The method of claim 15, wherein the welding recess is disposed in a first straight line and the second welding point is disposed in a second straight line substantially parallel to the first straight line.

20. The method of claim 15, wherein the second welding point is formed closer to a short side edge of the mask sheet than the welding recess.
